(19) United States
(12) Patent Application Publication
(10) Pub. No.: US 2026/0231573 A1
(43) Pub. Date: Aug. 6, 2026

(54) LINEAR LIGHT SOURCE MODULE

(71) Applicant: HARVATEK CORPORATION, Hsinchu City (TW)

(72) Inventors: CHI-FENG CHANG, Taichung City (TW); LIN-WUN WANG, Hsinchu City (TW); FENG-HUI CHUANG, New Taipei City (TW)

(21) Appl. No.: 19/464,629

(22) Filed: Jan. 30, 2026

(30) Foreign Application Priority Data
Feb. 5, 2025 (TW) 114104063

(51) Int. Cl. H10H 20/855; H10H 20/80; H10H 20/851; H10H 20/853; H10H 29/24

(52) U.S. Cl. CPC H10H 20/855; H10H 20/8512; H10H 20/853; H10H 20/882; H10H 29/24

(57) ABSTRACT

A linear light source module includes a substrate and multiple light-emitting elements. The substrate defines a first direction and a second direction that is perpendicular to the first direction. The light-emitting elements are disposed on the substrate, and are spaced apart from each other along the first direction. Each of the light-emitting elements includes a light-emitting unit and a light diffusion layer. The light-emitting unit has a top light-emitting surface, two first side light-emitting surfaces disposed opposite to each other along the first direction, and two second side light-emitting surfaces disposed opposite to each other along the second direction. The light diffusion layer covers the top light-emitting surface and the two second side light-emitting surfaces, and the two first side light-emitting surfaces are exposed from the light diffusion layer. Accordingly, a uniform light distribution is generated, and formation of bright spots and dark zones is prevented.

### CROSS-REFERENCE TO RELATED PATENT APPLICATION

This application claims the benefit of priority to Taiwan Patent Application No. 114104063, filed on February 5, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light source module, and more particularly to a linear light source module capable of generating a uniform light distribution.

### BACKGROUND OF THE DISCLOSURE

Light-emitting diodes (LED) have numerous advantages, and thus have a relatively wide range of application. Currently, various products that adopt an LED light source can be seen in daily life.

In the conventional technology, a plurality of LED elements are sequentially mounted on a substrate, so as to form a linear light source. Additional optical elements (e.g., a light guide plate and a diffusion plate) are disposed above the LED elements for enhancing brightness and light uniformity. However, in order to ensure a uniform distribution of light, a certain distance needs to be maintained between the LED elements and the diffusion plate. This is unbeneficial for volume reduction. Furthermore, a structural element (e.g., a spacer) that is present between the LED elements and the diffusion plate is likely to block or interfere with light from the LED elements, such that the brightness is not uniform. That is, bright spots or dark zones may be generated.

### SUMMARY OF THE DISCLOSURE

In response to the above-referenced technical inadequacies, the present disclosure provides a linear light source module, so as to solve technical problems of forming bright spots due to concentration of light at regions adjacent to light-emitting elements and presence of dark zones between the light-emitting elements.

In order to solve the above-mentioned problems, one of the technical aspects adopted by the present disclosure is to provide a linear light source module, which includes a substrate and a plurality of light-emitting elements. The substrate defines a first direction and a second direction that is perpendicular to the first direction. The light-emitting elements are disposed on the substrate, and are spaced apart from each other along the first direction. In the present disclosure, each of the light-emitting elements includes a light-emitting unit and a light diffusion layer. The light-emitting unit has a top light-emitting surface, two first side light-emitting surfaces that are disposed opposite to each other along the first direction, and two second side light-emitting surfaces that are disposed opposite to each other along the second direction. The light diffusion layer covers the top light-emitting surface and the two second side light-emitting surfaces, and the two first side light-emitting surfaces are exposed from the light diffusion layer.

In one of the possible or preferred embodiments, an interval between two adjacent ones of the light-emitting elements ranges between 1mm and 20mm.

In one of the possible or preferred embodiments, a thickness of the light diffusion layer ranges between 30μm and 150μm, and a material of the light diffusion layer contains titanium dioxide particles. Based on a total weight of the material of the light diffusion layer being 100wt%, a content of the titanium dioxide particles ranges between 10wt% and 60wt%.

In one of the possible or preferred embodiments, each of the light-emitting elements includes a wavelength conversion layer disposed between the light-emitting unit and the light diffusion layer, and the wavelength conversion layer covers the top light-emitting surface, the two first side light-emitting surfaces, and the two second side light-emitting surfaces.

In one of the possible or preferred embodiments, a thickness of the wavelength conversion layer ranges between 30μm and 150μm.

In one of the possible or preferred embodiments, each of the light-emitting elements includes a light-permeable layer disposed between the light diffusion layer and the wavelength conversion layer, and the light-permeable layer is disposed above the top light-emitting surface.

In one of the possible or preferred embodiments, each of the light-emitting elements includes a light-permeable layer disposed between the light-emitting unit and the light diffusion layer.

In one of the possible or preferred embodiments, the light-permeable layer covers the top light-emitting surface, the two first side light-emitting surfaces, and the two second side light-emitting surfaces.

In one of the possible or preferred embodiments, the light-permeable layer is filled in gaps between the light diffusion layer and the two second side light-emitting surfaces, and no gap is present between the light diffusion layer and the top light-emitting surface.

In one of the possible or preferred embodiments, the light-permeable layer contains diffusion particles.

Therefore, in the linear light source module provided by the present disclosure, by virtue of “the plurality of light-emitting elements being disposed on the substrate and spaced apart from each other along a length direction of the substrate,” “the light diffusion layer covering the top light-emitting surface of the light-emitting unit and two opposite side light-emitting surfaces of the light-emitting unit along a width direction of the substrate,” and “two opposite side light-emitting surfaces of the light-emitting unit along the length direction of the substrate being exposed from the light diffusion layer,” volume reduction can be achieved whilst generating a more uniform light distribution. In this way, formation of the bright spots and the dark zones can be prevented.

Furthermore, since the light-emitting elements adopt the above-mentioned partial coverage design, the linear light source module of the present disclosure can generate a uniform light distribution without needing additional optical elements (e.g., a light guide plate and a diffusion plate). On this basis, a volume of a module is reduced, and a quantity of the light-emitting elements is decreased.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a linear light source module according to the present disclosure;

FIG. 2 is a schematic cross-sectional view taken along line II-II of FIG. 1 and showing a structure of a light-emitting element according to a first embodiment of the present disclosure from one angle of view;

FIG. 3 is a schematic cross-sectional view taken along line III-III of FIG. 1 and showing the structure of the light-emitting element according to the first embodiment of the present disclosure from another angle of view;

FIG. 4 is a schematic cross-sectional view taken along line II-II of FIG. 1 and showing the structure of a variation of the light-emitting element according to the first embodiment of the present disclosure from one angle of view;

FIG. 5 is a schematic cross-sectional view taken along line III-III of FIG. 1 and showing the structure of the variation of the light-emitting element according to the first embodiment of the present disclosure from another angle of view;

FIG. 6 is a schematic cross-sectional view taken along line II-II of FIG. 1 and showing a structure of a light-emitting element according to a second embodiment of the present disclosure from one angle of view;

FIG. 7 is a schematic cross-sectional view taken along line III-III of FIG. 1 and showing the structure of the light-emitting element according to the second embodiment of the present disclosure from another angle of view;

FIG. 8 is a schematic cross-sectional view taken along line II-II of FIG. 1 and showing a structure of a light-emitting element according to a third embodiment of the present disclosure from one angle of view;

FIG. 9 is a schematic cross-sectional view taken along line III-III of FIG. 1 and showing the structure of the light-emitting element according to the third embodiment of the present disclosure from another angle of view;

FIG. 10 is a schematic cross-sectional view taken along line II-II of FIG. 1 and showing the structure of a variation of the light-emitting element according to the third embodiment of the present disclosure from one angle of view; and

FIG. 11 is a schematic cross-sectional view taken along line III-III of FIG. 1 and showing the structure of the variation of the light-emitting element according to the third embodiment of the present disclosure from another angle of view.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

Unless otherwise stated, the material(s) used in any described embodiment is/are commercially available material(s) or may be prepared by methods known in the art, and the operation(s) or instrument(s) used in any described embodiment is/are conventional operation(s) or instrument(s) generally known in the related art.

### First Embodiment

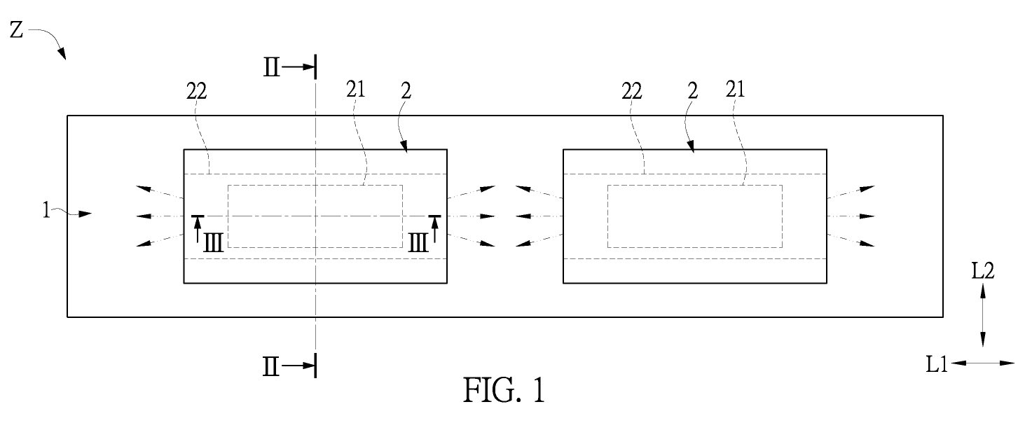

Referring to FIG. 1 to FIG. 3, a first embodiment of the present disclosure provides a linear light source module Z, which includes a substrate 1 and a plurality of light-emitting elements 2. The substrate 1 defines a first direction L1 and a second direction L2 that is perpendicular to the first direction L1. The first direction L1 is a length direction of the substrate 1. The second direction L2 is a width direction of the substrate 1. The light-emitting elements 2 are disposed on the substrate 1 and are spaced apart from each other along the first direction L1. Each of the light-emitting elements 2 includes a light-emitting unit 21 and a light diffusion layer 22 that is configured to diverge emergent light of the light-emitting unit 21. Light-emitting colors of the light-emitting elements 2 can be the same and can also be different from each other.

It should be noted that, in each of the light-emitting elements 2, the light diffusion layer 22 partially covers the light-emitting unit 21. That is, the light diffusion layer 22 does not completely cover all light-emitting surfaces of the light-emitting unit 21. Specifically, the light-emitting unit 21 has a top light-emitting surface 211, two first side light-emitting surfaces 212 that are disposed opposite to each other along the first direction L1, and two second side light-emitting surfaces 213 that are disposed opposite to each other along the second direction L2. The top light-emitting surface 211 and the two second side light-emitting surfaces 213 are covered by the light diffusion layer 22, and the two first side light-emitting surfaces 212 are exposed from the light diffusion layer 22 (i.e., the light diffusion layer 22 does not cover the two first side light-emitting surfaces 212). Hence, emergent light of the top light-emitting surface 211 and the two second side light-emitting surfaces 213 will not concentrate only at regions that are adjacent to the light-emitting unit 21 but will partially exit along the first direction L1 due to the light diffusion layer 22. In this way, light is uniformly distributed for regions away from the light-emitting unit 21, thereby achieving an effect of removing dark zones.

Due to adopting the light-emitting elements 2 with the above-mentioned partial coverage design, the linear light source module Z can generate a uniform light distribution without needing additional optical elements (e.g., a light guide plate and a diffusion plate). On this basis, a volume of a module can be reduced, and a quantity of the light-emitting elements 2 can be decreased. Under the circumstance where the quantity of the light-emitting elements 2 is decreased, an interval between two adjacent ones of the light-emitting elements 2 can be adjusted within a range of between 1 mm and 20 mm according to the design of the module.

Specifically, the substrate 1 can be an electrically conductive substrate, which includes a plurality of contact pads and a plurality of electrically conductive structures (e.g., conductive vias and wiring). The light-emitting element 2 can be a flip chip CSP (chip-scale package) element. No gap is present between the light diffusion layer 22 and the top light-emitting surface 211 and the two second side light-emitting surfaces 213 of the light-emitting unit 21. In practice, a visible light-emitting diode can be used as the light-emitting unit 21. The light diffusion layer 22 can be formed by spraying, printing, dispensing, or compression molding, and a thickness of the light diffusion layer 22 ranges between 30 μm and 150 μm. In addition, a material of the light diffusion layer 22 contains titanium dioxide particles. Based on a total weight of the material of the light diffusion layer 22 being 100 wt%, a content of the titanium dioxide particles ranges between 10 wt% and 60 wt%.

It should be noted that the thickness of the light diffusion layer 22 and the content of the titanium dioxide particles contained in the light diffusion layer 22 can both be adjusted according to requirements. For example, the thickness of the light diffusion layer 22 on the top light-emitting surface 211 of the light-emitting unit 21 can be increased, or the content of the titanium dioxide particles can be increased, so as to reduce brightness of a light output surface 201 (a forward light output surface) of the light-emitting element 2. Alternatively, the thickness of the light diffusion layer 22 on the second side light-emitting surface 213 of the light-emitting unit 21 can be increased, or the content of the titanium dioxide particles can be increased, so as to reduce brightness of a light output surface 202 (a lateral light output surface) of the light-emitting element 2.

In the present embodiment, the thickness of the light diffusion layer 22 can be 30 μm, 40 μm, 50 μm, 60 μm, 70 μm, 80 μm, 90 μm, 100 μm, 110 μm, 120 μm, 130 μm, 140 μm, or 150 μm. The content of the titanium dioxide particles in the light diffusion layer 22 can be 10 wt%, 15 wt%, 20 wt%, 25 wt%, 30 wt%, 35 wt%, 40 wt%, 45 wt%, 50 wt%, 55 wt%, or 60 wt%.

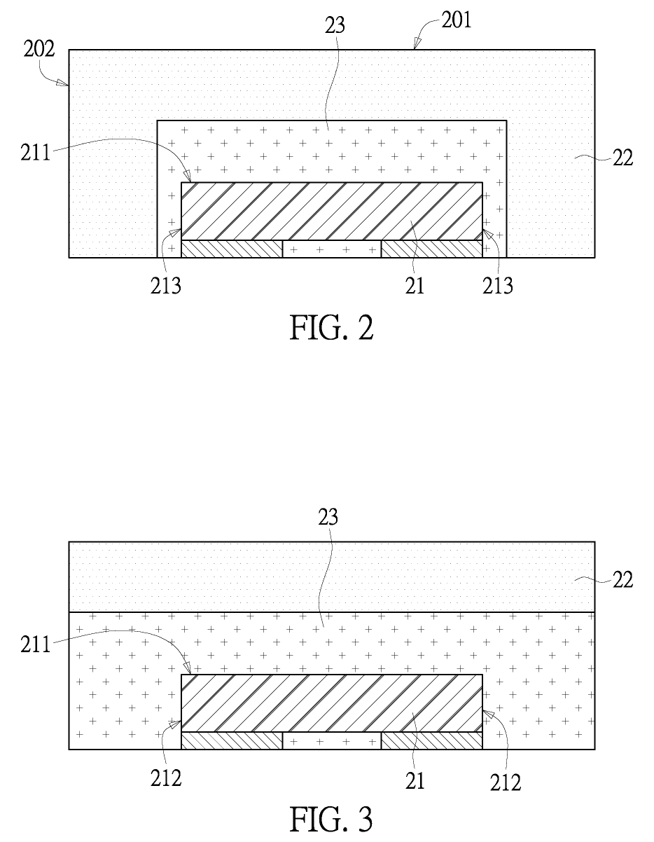

As shown in FIG. 2 and FIG. 3, in the linear light source module Z of the present disclosure, each of the light-emitting elements 2 can further include a wavelength conversion layer 23 to convert light from the light-emitting unit 21 into emergent light having different wavelengths. Specifically, the wavelength conversion layer 23 is disposed between the light-emitting unit 21 and the light diffusion layer 22, and the light-emitting unit 21, the light diffusion layer 22, and the wavelength conversion layer 23 are tightly and seamlessly formed as one piece. The wavelength conversion layer 23 covers the top light-emitting surface 211, the two first side light-emitting surfaces 212, and the two second side light-emitting surfaces 213 of the light-emitting unit 21. In practice, the wavelength conversion layer 23 can be formed by spraying, printing, dispensing, or compression molding, and a thickness of the wavelength conversion layer 23 ranges between 30μm and 150μm. Moreover, the wavelength conversion layer 23 contains one or more phosphors, and the phosphors are distributed in the wavelength conversion layer 23 in a substantially uniform manner. The wavelength conversion layer 23 can be formed by a single layer or can be formed by lamination of multiple layers.

It should be noted that the thickness of the wavelength conversion layer 23 can be adjusted according to requirements. For example, the thickness of the wavelength conversion layer 23 on the top light-emitting surface 211 of the light-emitting unit 21 can be increased to enhance lateral output light intensity. In the present embodiment, the thickness of the wavelength conversion layer 23 can be 30 μm, 40 μm, 50 μm, 60 μm, 70 μm, 80 μm, 90 μm, 100 μm, 110 μm, 120 μm, 130 μm, 140 μm, or 150 μm.

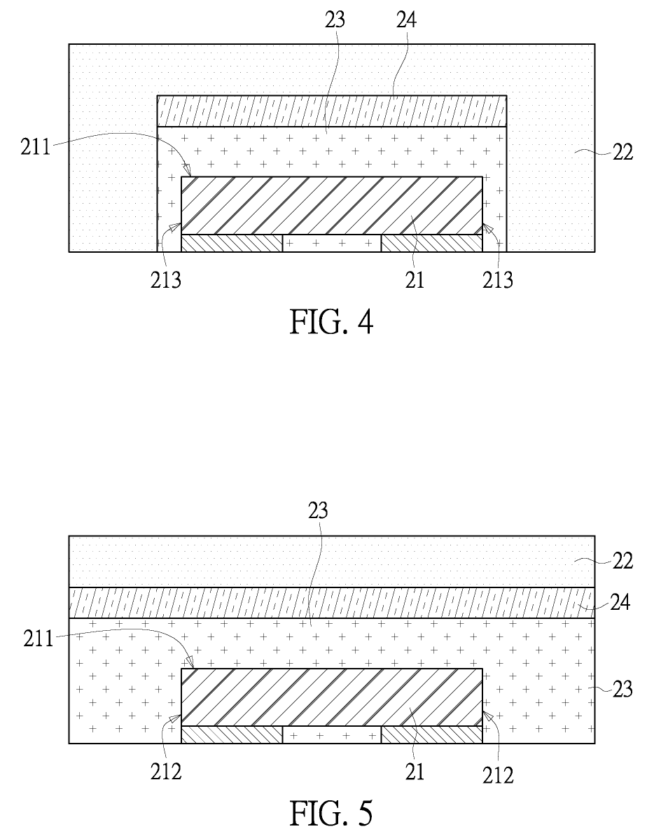

Reference is also made to FIG. 4 and FIG. 5. In the linear light source module Z of the present disclosure, each of the light-emitting elements 2 can further include a light-permeable layer 24 to increase a distance between the top light-emitting surface 211 of the light-emitting unit 21 and the light diffusion layer 22. In detail, the light-permeable layer 24 is disposed between the light diffusion layer 22 and the wavelength conversion layer 23, and the light diffusion layer 22, the wavelength conversion layer 23, and the light-permeable layer 24 are tightly and seamlessly formed as one piece. Moreover, the light-permeable layer 24 is disposed above the top light-emitting surface 211 of the light-emitting unit 21 and allows penetration of the light from the light-emitting unit 21. Hence, a thickness of the light-permeable layer 24 can be adjusted to increase a light extraction efficiency and enhance the lateral output light intensity. In practice, the light-permeable layer 24 can be an optical transparent layer formed by a highly transparent resin material, such as an epoxy resin, an acrylic resin, polycarbonates, or silicone.

### Second Embodiment

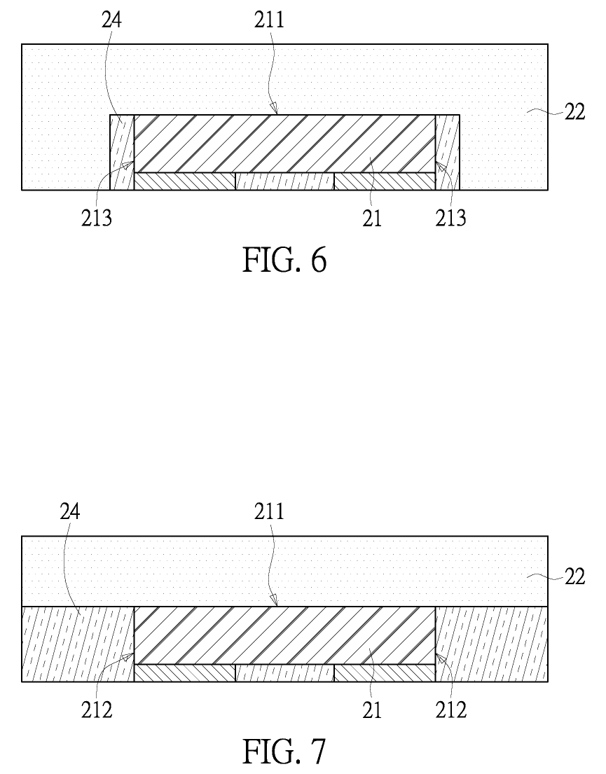

Referring to FIG. 6 and FIG. 7, which are to be read in conjunction with FIG. 1, a second embodiment of the present disclosure provides a linear light source module Z, which includes a substrate 1 and a plurality of light-emitting elements 2. The substrate 1 defines a first direction L1 and a second direction L2 that is perpendicular to the first direction L1. The light-emitting elements 2 are disposed on the substrate 1 and are spaced apart from each other along the first direction L1. Each of the light-emitting elements 2 includes a light-emitting unit 21 and a light diffusion layer 22. The light-emitting unit 21 has a top light-emitting surface 211, two first side light-emitting surfaces 212 that are disposed opposite to each other along the first direction L1, and two second side light-emitting surfaces 213 that are disposed opposite to each other along the second direction L2. The light diffusion layer 22 covers the top light-emitting surface 211 and the two second side light-emitting surfaces 213, and the two first side light-emitting surfaces 212 are exposed from the light diffusion layer 22.

Different from the first embodiment, a light-permeable layer 24 is disposed between the light-emitting unit 21 and the light diffusion layer 22 in each of the light-emitting elements 2. In addition, the light-emitting unit 21, the light diffusion layer 22, and the light-permeable layer 24 are tightly and seamlessly formed as one piece. Specifically, the light-permeable layer 24 is filled in gaps between the light diffusion layer 22 and the two second side light-emitting surfaces 213 of the light-emitting unit 21, and no gap is present between the light diffusion layer 22 and the top light-emitting surface 211 of the light-emitting unit 21.

Relevant technical details mentioned in the first embodiment are still valid in the present embodiment, and will not be repeated herein for the sake of brevity. Similarly, the technical details mentioned in the present embodiment can also be applied in the first embodiment.

### Third Embodiment

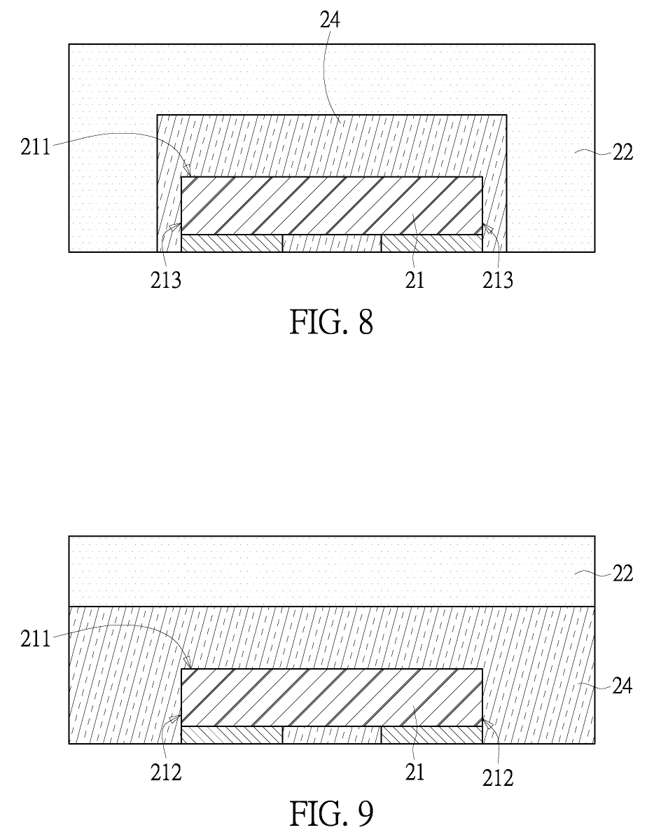

Referring to FIG. 8 and FIG. 9, which are to be read in conjunction with FIG. 1, a third embodiment of the present disclosure provides a linear light source module Z, which includes a substrate 1 and a plurality of light-emitting elements 2. The substrate 1 defines a first direction L1 and a second direction L2 that is perpendicular to the first direction L1. The light-emitting elements 2 are disposed on the substrate 1 and are spaced apart from each other along the first direction L1. Each of the light-emitting elements 2 includes a light-emitting unit 21 and a light diffusion layer 22. The light-emitting unit 21 has a top light-emitting surface 211, two first side light-emitting surfaces 212 that are disposed opposite to each other along the first direction L1, and two second side light-emitting surfaces 213 that are disposed opposite to each other along the second direction L2. The light diffusion layer 22 covers the top light-emitting surface 211 and the two second side light-emitting surfaces 213, and the two first side light-emitting surfaces 212 are exposed from the light diffusion layer 22.

Different from the first embodiment, a light-permeable layer 24 is disposed between the light-emitting unit 21 and the light diffusion layer 22 in each of the light-emitting elements 2. In addition, the light-emitting unit 21, the light diffusion layer 22, and the light-permeable layer 24 are tightly and seamlessly formed as one piece. Specifically, the light-permeable layer 24 covers the top light-emitting surface 211, the two first side light-emitting surfaces 212, and the two second side light-emitting surfaces 213 of the light-emitting unit 21.

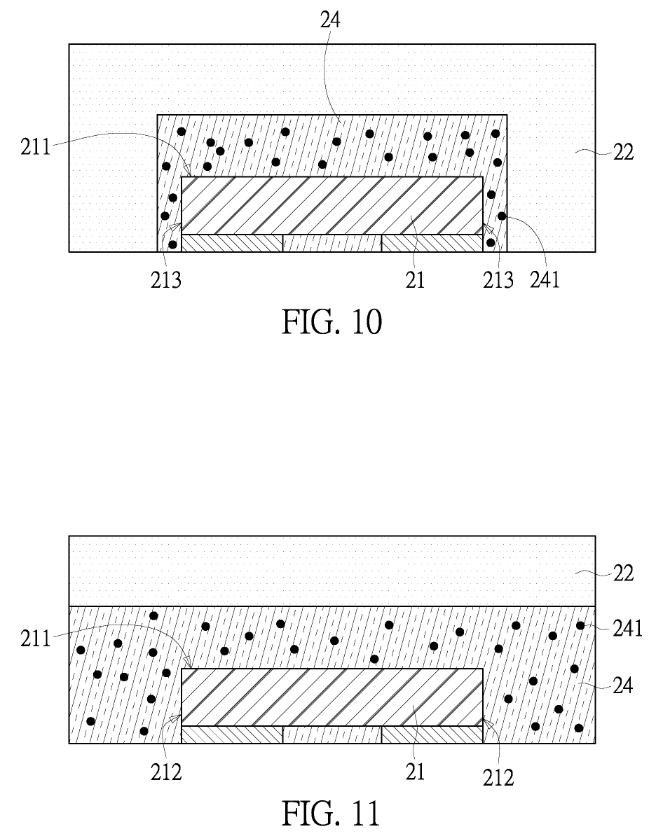

As shown in FIG. 10 and FIG. 11, if necessary, the light-permeable layer 24 can contain diffusion particles 241 to further enhance light uniformity. The diffusion particles 241 can use aluminum oxide (Al₂O₃), silicon dioxide (SiO₂), titanium dioxide (TiO₂), or any combination thereof, and are not limited thereto.

Relevant technical details mentioned in the above-mentioned embodiments are still valid in the present embodiment, and will not be repeated herein for the sake of brevity. Similarly, the technical details mentioned in the present embodiment can also be applied in the above-mentioned embodiments.

### Beneficial Effects of the Embodiments

In conclusion, in the linear light source module provided by the present disclosure, by virtue of “the plurality of light-emitting elements being disposed on the substrate and spaced apart from each other along the length direction of the substrate,” “the light diffusion layer covering the top light-emitting surface of the light-emitting unit and two opposite side light-emitting surfaces of the light-emitting unit along the width direction of the substrate,” and “two opposite side light-emitting surfaces of the light-emitting unit along the length direction of the substrate being exposed from the light diffusion layer,” volume reduction can be achieved whilst generating a more uniform light distribution. In this way, formation of bright spots and dark zones can be prevented.

Furthermore, since the light-emitting elements adopt the above-mentioned partial coverage design, the linear light source module of the present disclosure can generate a uniform light distribution without needing additional optical elements (e.g., a light guide plate and a diffusion plate). On this basis, the volume of the module is reduced, and the quantity of the light-emitting elements is decreased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A linear light source module, comprising:
a substrate, wherein the substrate defines a first direction and a second direction that is perpendicular to the first direction; and
a plurality of light-emitting elements disposed on the substrate and spaced apart from each other along the first direction, wherein each of the plurality of light-emitting elements includes a light-emitting unit and a light diffusion layer, and the light-emitting unit has a top light-emitting surface, two first side light-emitting surfaces that are disposed opposite to each other along the first direction, and two second side light-emitting surfaces that are disposed opposite to each other along the second direction; and wherein the light diffusion layer covers the top light-emitting surface and the two second side light-emitting surfaces, and the two first side light-emitting surfaces are exposed from the light diffusion layer.

2. The linear light source module according to claim 1, wherein an interval between two adjacent ones of the plurality of light-emitting elements ranges between 1mm and 20mm.

3. The linear light source module according to claim 1, wherein a thickness of the light diffusion layer ranges between 30μm and 150μm, and a material of the light diffusion layer contains titanium dioxide particles; and wherein, based on a total weight of the material of the light diffusion layer being 10wt%, a content of the titanium dioxide particles ranges between 10wt% and 60wt%.

4. The linear light source module according to claim 1, wherein each of the plurality of light-emitting elements includes a wavelength conversion layer disposed between the light-emitting unit and the light diffusion layer, and the wavelength conversion layer covers the top light-emitting surface, the two first side light-emitting surfaces, and the two second side light-emitting surfaces.

5. The linear light source module according to claim 4, wherein a thickness of the wavelength conversion layer ranges between 30μm and 150μm.

6. The linear light source module according to claim 4, wherein each of the plurality of light-emitting elements includes a light-permeable layer disposed between the light diffusion layer and the wavelength conversion layer, and the light-permeable layer is disposed above the top light-emitting surface.

7. The linear light source module according to claim 1, wherein each of the plurality of light-emitting elements includes a light-permeable layer disposed between the light-emitting unit and the light diffusion layer.

8. The linear light source module according to claim 7, wherein the light-permeable layer covers the top light-emitting surface, the two first side light-emitting surfaces, and the two second side light-emitting surfaces.

9. The linear light source module according to claim 8, wherein the light-permeable layer contains diffusion particles.

10. The linear light source module according to claim 7, wherein the light-permeable layer is filled in gaps between the light diffusion layer and the two second side light-emitting surfaces, and no gap is present between the light diffusion layer and the top light-emitting surface.

11. The linear light source module according to claim 10, wherein the light-permeable layer contains diffusion particles.
